(19) United States
(12) Patent Application Publication
(10) Pub. No.: US 2006/0270209 A1
(43) Pub. Date: Nov. 30, 2006

(54) Process for producing transparent electrode

(75) Inventors: Akira Mitsui, Yokohama-shi (JP); Hidefumi Odaka, Yokohama-shi (JP); Shigeaki Yonemori, Yokohama-shi (JP); Yasuhiko Akao, Yonezawa-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: ASAHI GLASS COMPANY, LIMITED, Tokyo (JP)

(21) Appl. No.: 11/500,896

(22) Filed: Aug. 9, 2006

Related U.S. Application Data
(63) Continuation of application No. PCT/JP05/01527, filed on Feb. 2, 2005.

(30) Foreign Application Priority Data
Feb. 9, 2004 (JP) 2004-032039
Feb. 24, 2004 (JP) 2004-048426
Mar. 30, 2004 (JP) 2004-099057

(51) Int. Cl. H01L 21/44

(52) U.S. Cl. 438/608

(57) ABSTRACT

To provide a process for producing a transparent electrode comprising a tin oxide film which can readily be patterned, which can be realized at a low cost, and which has low resistivity and is excellent in transparency. A process for producing a transparent electrode having a patterned tin oxide film formed on a substrate, which comprises a step of forming a tin oxide film having light absorption characteristics on a substrate, a patterning step of removing part of the tin oxide film having light absorption characteristics, and a step of subjecting the patterned tin oxide film having light absorption characteristics to heat treatment to obtain a tin oxide film.

### BACKGROUND OF THE INVENTION

1. Field of the Invention

The present invention relates to a process for producing a transparent electrode suitable particularly for a flat panel display.

2. Discussion of Background

Heretofore, for flat panel displays such as liquid crystal display devices, plasma displays and organic LED, a substrate provided with a transparent conductive film has been used as a transparent electrode. As material of the transparent conductive film, indium oxide, zinc oxide and tin oxide materials have been known. ITO (indium tin oxide) as the indium oxide material is particularly famous and used widely. It is because of low resistivity properties and favorable patterning properties that ITO is widely used. However, it has been known that indium resources are scarce, and development of an alternative has been desired.

Tin oxide (SnO₂) is a material promising as the alternative. In order to form a pattern of e.g. a conductive circuit or an electrode, part of a tin oxide film has to be selectively etched. However, a tin oxide film is chemically stable and thereby can not easily be etched. In order to dissolve the above problem, a process of patterning a tin oxide film by lift-off process has been disclosed (e.g. Patent Document 1). However, lift-off process is not suitable for products for which high pattern accuracy is required, as protrusions called spikes are formed at the edge of the formed pattern, which may cause electric failure. Further, mechanical washing such as brush washing will be required to remove the spikes, and the formed pattern may be damaged resultingly.

Further, as a process of forming a high precision pattern, a process of forming a resist pattern on a tin oxide film by means of photolithography and then employing Cr+HCl, a HI solution or the like which is an etching liquid providing solubility of the tin oxide film, has been already generally known. However, since the etching liquid has a short life, it is required to use an apparatus such as an electrolytic cell in combination, and complicated operation is required, such that the treatment atmosphere has to be controlled.

Further, a process of forming a tin sulfide film on a substrate, followed by patterning, and then heating the film to oxide it, has been disclosed (e.g. Patent Document 2). Tin sulfide is a material which is easily etched as compared with tin oxide. However, in the above process, since tin sulfide is changed to tin oxide by heating, its volume will significantly change, and the stress of the film tends to be high, whereby peeling of the film or cracks are likely to occur.

Patent Document 1: JP-A-6-280055

Patent Document 2: JP-A-2-234310

Patent Document 3: JP-A-2001-79675

### SUMMARY OF THE INVENTION

It is an object of the present invention to provide a process for producing a transparent electrode comprising a tin oxide film, which is easily patterned, which can be prepared at a low cost and which has low resistivity and excellent transparency.

Namely, the present invention provides the following process for producing a transparent electrode and film.

(1) A process for producing a transparent electrode comprising a patterned tin oxide film formed on a substrate, which comprises a step of forming a tin oxide film having light absorption characteristics on a substrate, a patterning step of removing part of the tin oxide film having light absorption characteristics, and a step of subjecting the patterned tin oxide film having light absorption characteristics to heat treatment to obtain a tin oxide film.

(2) A process for producing a transparent electrode comprising a patterned tin oxide film formed on a substrate, which comprises a step of forming a SnO₂₋ₓ (0.3≦x≦1.95) film on a substrate, a patterning step of removing part of the SnO₂₋ₓ film, and a step of subjecting the patterned SnO₂₋ₓ film to heat treatment to obtain a tin oxide film.

(3) A process for producing a transparent electrode comprising a patterned tin oxide film formed on a substrate, which comprises a step of forming a tin oxide film having a density of at most 6.5 g/cm³ on a substrate, a patterning step of removing part of the tin oxide film having a density of at most 6.5 g/cm³, and a step of subjecting the patterned tin oxide film having a density of at most 6.5 g/cm³ to heat treatment to obtain a tin oxide film.

(4) The above process for producing a transparent electrode, wherein the step of forming a tin oxide film having light absorption characteristics is carried out by a sputtering method, and the temperature of the substrate at the time of deposition is at most 150° C.

(5) The above process for producing a transparent electrode, wherein the step of forming a SO₂₋ₓ film is carried out by a sputtering method, and the temperature of the substrate at the time of deposition is at most 150° C.

(6) The above process for producing a transparent electrode, wherein the step of forming a tin oxide film having a density of at most 6.5 g/cm³ is carried out by a sputtering method, and the temperature of the substrate at the time of deposition is at most 150° C.

(7) The above process for producing a transparent electrode, wherein in the sputtering method, the deposition is carried out by using an oxide target, and the amount of an oxidizing gas in a sputtering gas is at most 10 vol % of the entire sputtering gas.

(8) The above process for producing a transparent electrode, wherein in the sputtering method, the deposition is carried out by using a metal target.

(9) The above process for producing a transparent electrode, wherein the tin oxide film is a crystalline film.

(10) The above process for producing a transparent electrode, wherein the temperature at the time of the heat treatment is from 300 to 700° C.

(11) The above process for producing a transparent electrode, wherein the tin oxide film contains at least one additive metal selected from the group consisting of titanium, niobium, zirconium, antimony, tantalum, tungsten and rhenium.

(12) The above process for producing a transparent electrode, wherein the amount of the additive metal is from 0.1 to 30 atomic % to Sn.

(13) The above process for producing a transparent electrode, wherein the patterning is carried out by dissolving part of the film by an etching liquid.

(14) The above process for producing a transparent electrode, wherein the patterning is carried out by removing part of the film by a laser beam, and the wavelength of the laser beam is from 350 to 600 nm.

(15) The above process for producing a transparent electrode, wherein the patterning is carried out by removing part of the film by a laser beam, the wavelength of the laser beam is from 350 to 600 nm, and the absorptivity of the film at the wavelength of the laser beam is at least 5%.

(16) The above process for producing a transparent electrode, wherein the transparent electrode has a sheet resistivity of from 5 to 5,000 Ω/□.

(17) A film capable of being patterned and forming a patterned tin oxide film on a substrate, which is a tin oxide film having light absorbing characteristics.

(18) A film capable of being patterned and forming a patterned tin oxide film on a substrate, which is a SnO₂₋ₓ (0.3≦x≦1.95) film.

(19) A film capable of being patterned and forming a patterned tin oxide film on a substrate, which is a tin oxide film having a density of at most 6.5 g/cm³.

According to the process for producing a transparent electrode of the present invention, a transparent electrode excellent in transparency and electrical conductivity and suitable particularly for a flat panel display, can be formed at a low cost.

### BRIEF DESCRIPTION OF THE DRAWINGS

FIG. 1 is a graph illustrating the relation, in a case where an oxygen gas is contained in a sputtering gas, of the oxygen gas concentration with the etching rate for a SnO₂₋ₓ film, and the luminous transmittance and the volume resistivity after heat treatment.

FIG. 2 is a graph illustrating the relation, in a case where a carbon dioxide gas is contained in a sputtering gas, of the carbon dioxide gas concentration with the etching rate for a SnO₂₋ₓ film, and the luminous transmittance and the volume resistivity after heat treatment.

FIG. 3 is a graph illustrating the relation, in a case where a nitrogen gas is contained in a sputtering gas, of the nitrogen gas concentration with the etching rate for a SnO₂₋ₓ film, and the luminous transmittance and the volume resistivity after heat treatment.

FIG. 4 is a graph illustrating the relation between the heat treatment temperature and the volume resistivity of transparent electrodes.

FIG. 5 is a graph illustrating the relation between the heat treatment temperature and the luminous transmittance of transparent electrodes.

FIG. 6 is a graph illustrating the change of the deposition rate depending on the gas pressure.

FIG. 7 is a graph illustrating the change of the sheet resistivity depending on the gas pressure.

FIG. 8 is a graph illustrating the change of the deposition rate depending on the voltage.

FIG. 9 is a graph illustrating the change of the sheet resistivity depending on the voltage.

FIG. 10 is a graph illustrating the change of the visible light transmittance depending on the voltage before and after heat treatment.

FIG. 11 is a drawing illustrating the process for producing a transparent electrode of the present invention.

### DETAILED DESCRIPTION OF THE PREFERRED EMBODIMENTS

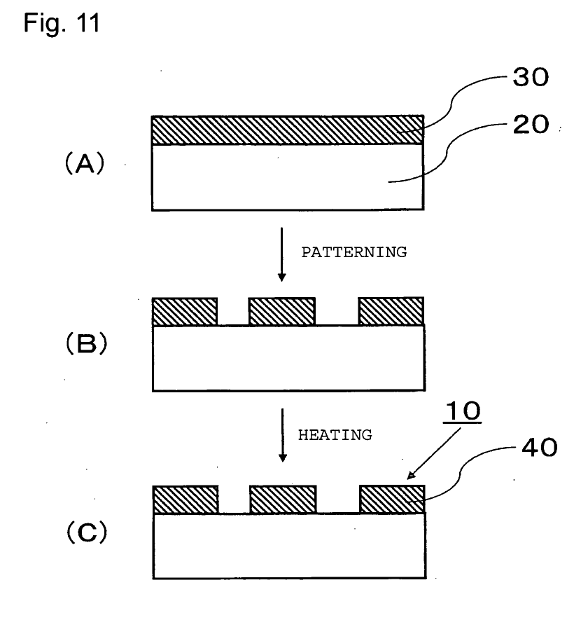

The process for producing a transparent electrode of the present invention is illustrated in FIG. 11. The present invention provides a process for producing a transparent electrode 10 having a patterned tin oxide film 40 formed on a substrate 20, which comprises a step (A) of forming a precursor film 30 as described hereinafter on a substrate, a patterning step (B) and a step (C) of subjecting the patterned precursor film 30 to heat treatment to obtain a tin oxide film.

A tin oxide film (SnO₂ film) which is expected to be a promising material of a transparent electrode usually has no light absorption characteristics or very low light absorption characteristics if any, and it is thereby transparent for visible light. In order to prepare a transparent electrode comprising such a tin oxide film, it is considered to be simplest to remove part of the tin oxide film by wet etching. However, the tin oxide film having no or very low light absorption characteristics has very high acid resistivity and is thereby hardly soluble in an acidic solution. Further, a tin oxide film having a high density is also hardly soluble. Therefore, a tin oxide film has not been able to be etched with a conventional acidic solution, and its use for a transparent electrode has been difficult.

Further, as a method of patterning tin oxide, a method by means of a laser beam may also be considered. However, a transparent conductive film such as a tin oxide film has a low absorptivity for a light having a wavelength from near ultraviolet to visible region in many cases, and accordingly it is required to employ a laser beam in a wavelength region for which the transparent conductive film has a high absorptivity i.e. in near infrared wavelength region. As a laser beam having a wavelength in near infrared region, specifically, a YAG laser (wavelength: 1,064 nm) has been used. However, at this wavelength, in a case where the substrate is glass, due to absorption by impurities such as iron contained in the glass, the glass will absorb the laser beam upon irradiation with an intense laser beam, whereby the glass will be broken.

The present inventors have noted that a tin oxide film (hereinafter refereed as a colored tin oxide film) having light absorption characteristics or a film (SnO₂₋ₓ film) having oxygen deficiencies introduced to SnO₂ is easily dissolved in an etching liquid, and they have found that a transparent electrode comprising a tin oxide film which has hardly been patterned, can be formed by forming a colored tin oxide film on a substrate, followed by patterning and heating to obtain a tin oxide film. The film having light absorption characteristics means a film, of which the visible light transmittance Tᵥ is increased by at least 3% by heating in the air at 600° C. for 30 minutes. By heating in the air at 600° C. for 30 minutes, the colored tin oxide film is oxidized and becomes a stoichiometrically complete tin oxide film to which no oxygen deficiency introduced. Further, the present inventors have noted that a film (hereinafter referred to as a low density tin oxide film) having a rather low density (specifically a density of at most 6.5 g/cm³) is easily dissolved in an etching liquid, and they have found that a transparent electrode comprising a tin oxide film which has been hardly patterned, can be formed by forming a colored tin oxide film (low density tin oxide film) on a substrate, followed by patterning and heating to obtain a tin oxide film. By the above heating, the colored tin oxide film is oxidized and becomes a stoichiometrically complete tin oxide film to which no oxygen efficiency is introduced. By the above processes, a transparent electrode comprising a tin oxide film excellent in transparency and electrical conductivity, which has not been achieved, can be formed at a low cost. Hereinafter the colored tin oxide film, the SnO₂₋ₓ film and the low density tin oxide film will generically be referred to as a precursor film.

It is not completely understood why the SnO₂₋ₓ film is easily etched. However, it is considered that in a state where there are oxygen deficiencies, there are broken Sn—O bonds, that is, there are dangling bonds. Therefore, it is considered that if the oxygen deficiencies increase, the dangling bonds will increase, and the bonds will be weak as a whole resultingly. Therefore, it is considered that SnO₂₋ₓ is more likely to be dissolved in an etching liquid than SnO₂ having a stoichiometrically complete composition. Further, it is estimated that the SnO₂₋ₓ film is likely to be etched since it is a film close to a metal.

Further, it is not completely understood why the low density tin oxide film is easily etched, but it is considered to be because the bonds are weak as a whole from the same reasons as those of the SnO₂₋ₓ film.

The precursor film may contain at least one additive metal selected from the group consisting of titanium, niobium, zirconium, antimony, tantalum, tungsten and rhenium. The above additive metal will function as an additive (dopant) which imparts further electrical conductivity and heat resistivity to tin oxide. The additive metal is preferably present in a state where it is solid-solubilized in tin oxide in the film. The amount of the additive metal is preferably from 0.1 to 30 atomic % to Sn, in view of improvement in electrical conductivity and heat resistivity and improvement in etching performance. It is more preferably from 0.1 to 25 atomic %, particularly preferably from 0.1 to 10 atomic %, with a view to obtaining a transparent electrode having lower resistivity. The amount of the additive metal will not change between before and after patterning.

The content of metal elements other than Sn and the above additive metal in the precursor film, i.e. the content of unintended metal elements, is preferably at most 20 atomic % to Sn, with a view to not impairing excellent properties of tin oxide such as electrical conductivity and transparency. Further, a light element such as nitrogen or carbon may be contained within a range not to impair the characteristics of the present invention.

The precursor film has, in the case of patterning by a laser beam, an absorptivity at the laser wavelength of at least 5%, preferably at least 7%, in view of easy patterning by the laser beam. If it is less than 5%, the patterning efficiency tends to be poor, whereby desired patterning will hardly be carried out. The tin oxide film has a low absorptivity at a wavelength in near ultraviolet to visible region, and patterning by a laser beam having a wavelength in this range tends to be difficult. The wavelength of the laser beam is preferably from 350 to 1,300 nm, more preferably from 350 to 600 nm in view of patterning properties.

The precursor film is preferably amorphous in view of easy etching. If it is crystalline, basically no disturbance of molecular arrangement is present, and reactive ions contained in the etching liquid hardly infiltrate, whereby etching tends to be difficult. The amorphous precursor film is converted to a crystalline tin oxide film by heat treatment.

The formed precursor film will easily be dissolved in the etching liquid for ITO and is excellent in resistivity to washing with an alkaline solution.

In the SnO₂₋ₓ film, x is preferably from 0.3 to 1.95 (0.3≦x≦1.95), particularly preferably from 0.8 to 1.95, from 1.1 to 1.95, from 1.1 to 1.85, from 1.1 to 1.8, from 1.3 to 1.85, or from 1.3 to 1.7, and x is especially preferably from 1.5 to 1.85 or from 1.5 to 1.7, in view of a high etching rate and excellent transparency and electrical conductivity. When x is from 1.1 to 1.95, an etching rate so high as about 50 times at a maximum as compared with ITO can be obtained.

The density of the low density tin oxide film is at most 6.5 g/cm³ and at least 3.2 g/cm³, preferably at most 6.1 g/cm³. Within the above range, the etching rate can be made high, and excellent transparency and electrical conductivity will be obtained.

The colored tin oxide film means a film of which the visible light transmittance Tᵥ is increased by at least 3% by heating in the air at 600° C. for 30 minutes. Tᵥ may be increased by at least 10%, particularly at least 50%.

Further, the precursor film may contain a light element such as carbon or nitrogen. In the case of deposition by a sputtering method, a SnO₂₋ₓ film containing carbon or nitrogen can be formed by incorporating carbon dioxide or nitrogen in the sputtering gas. By the SnO₂₋ₓ film containing nitrogen, the etching rate for the SnO₂₋ₓ film can easily be adjusted.

A method of forming the precursor film is not particularly limited, but preferred is a sputtering method with a view to easily forming an amorphous film advantageous for etching. Further, the sputtering method is preferred also with a view to easily forming a film having a large area and a uniform film distribution. The sputtering method may be either a DC sputtering method or an AC sputtering method.

In the case of forming the precursor film by a sputtering method, the substrate temperature at the time of deposition is preferably at most 150° C. with a view to easily forming an amorphous film, particularly preferably at most 100° C. Further, deposition without heating is preferred in view of productivity.

In the case of deposition by a sputtering method, the target to be used may be an oxide target or a metal target. An oxide target is preferred with a view to obtaining a precursor film with a uniform composition distribution. A metal target is preferred with a view to easily adjusting the amount of oxygen deficiencies in the film.

In the case of deposition by using an oxide target, the atmospheric gas (sputtering gas) at the time of deposition is preferably an inert gas such as an argon gas with a view to easily obtaining a SnO₂₋ₓ film. As the inert gas, a helium gas, a neon gas, a krypton gas or a xenon gas may also be used. It is possible to use a nitrogen gas as the sputtering gas. However, an oxidizing gas such as oxygen is unfavorable as the sputtering gas, since the film tends to have a stoichiometrically complete composition and tends to be crystallized. The amount of the oxidizing gas in the sputtering gas is preferably at most 10 vol % of the entire sputtering gas. Further, the oxide target is formed, for example, by hot pressing a powder mixture obtained by mixing an oxide of the above-described additive metal and a powder of tin oxide, but the method for producing the oxide target is not particularly limited.

Further, in the case of deposition by using an oxide target, a higher deposition rate will be obtained when the gas pressure is lower, but the gas pressure is preferably from 2 to 5 Pa in view of the sheet resistivity of the tin oxide film. If it exceeds 5 Pa, the deposition rate tends to be low. Further, a higher deposition rate will be obtained when the electric power is higher, depending upon the area of the target.

In the case of deposition by using a metal target, the atmospheric gas (sputtering gas) at the time of deposition is preferably a mixed gas having an oxidizing gas added to an inert gas, with a view to easily obtaining a SnO₂₋ₓ film. The inert gas may, for example, be at least one member selected from the group consisting of an argon gas, a helium gas, a neon gas, a krypton gas and a xenon gas. Further, the oxidizing gas may be at least one member selected from the group consisting of an oxygen gas and a carbon dioxide gas. In a case where an oxygen gas is used as the oxidizing gas, the amount of the oxygen gas in the sputtering gas is preferably from 10 to 60 vol %, or from 20 to 60 vol %, particularly preferably from 30 to 55 vol %, in view of transparency and electrical conductivity, depending upon the power density. Further, in a case where a carbon dioxide gas is used as the oxidizing gas, the amount of the carbon dioxide gas in the sputtering gas is preferably from 5 to 80 vol %, from 10 to 80 vol %, or from 15 to 80 vol %, particularly preferably from 30 to 80 vol %, in view of transparency and electrical conductivity, depending upon the power density.

Further, in the case of deposition by using a metal target, a higher deposition rate will be obtained when the gas pressure is lower, but the gas pressure is preferably adjusted and it is preferably at most 4 Pa in view of the sheet resistivity of the tin oxide film. Further, the electric power is preferably higher to obtain a higher deposition rate. However, in a case where the area of the target is 182 cm² (6 inch circular target), the electric power is preferably from 435 to 470 V in view of the sheet resistivity of the tin oxide film.

Further, a nitrogen gas may be added to the sputtering gas. For example, when a film having a two-layer structure comprising a tin oxide film and an undercoat layer is to be etched, it is required that the etching rates for the two layers are the same, and the etching rates will easily be adjusted without changing the properties of the film by adding a nitrogen gas. The amount of the nitrogen gas in the sputtering gas is preferably from 0.1 to 50 vol %, particularly preferably from 10 to 30 vol %, in view of adjustment of the etching rate. In a case where a nitrogen gas is added, it is preferred to use carbon dioxide as the oxidizing gas with a view to obtaining a low resistivity.

After formation of the precursor layer, patterning is carried out. As patterning, a patterning method of dissolving part of the film with an etching liquid and a method of removing part of the film by a laser beam may, for example, be mentioned.

In the case of carrying out patterning by dissolving part of the precursor film with an etching liquid, the etching liquid is preferably an acidic mixed aqueous solution containing as the main components ferric chloride (FeCl₃) and hydrochloric acid, or ferric chloride and hydrobromic acid, since the precursor film can be dissolved without any influence over the substrate, a controllable etching rate will be obtained, and the degree of side etching tends to be small. By using such an etching liquid, the existing etching facilities and etching technique for the ITO film can be employed, and it is not necessary to newly provide an apparatus such as an electrolytic cell, such being advantageous in view of cost. Specifically, a combination of from 0.01 to 3 mol/liter of ferric chloride and from 0.1 to 9 mol/liter of hydrochloric acid as the hydrogen ion concentration, and a combination of from 0.0005 to 0.5 mol/liter of ferric chloride and from 3 to 9 mol/liter of hydrobromic acid as the hydrogen ion concentration, may be mentioned as preferred examples, with a view to obtaining excellent patterning properties with a side etching amount of from 2 to 4 μm. By such a mixed aqueous solution, it is difficult to directly etch the SnO₂ film. The etching rate for the precursor film is, in a case where a mixed aqueous solution containing 1.8 mol/liter of FeCl₃ and 5 mol/liter of HCl is adjusted and used as an etching liquid, preferably at least 1.5 nm/sec, whereby etching can be carried out in the same manner as ITO.

At the time of etching, the temperature of the etching liquid is preferably from 15 to 80° C., particularly preferably from 40 to 60° C. If it is less than 15° C., the etching rate tends to be low, and if it exceeds 80° C., the etching liquid is likely to evaporate, whereby no stable etching rate is likely to be obtained. Further, the precursor film is hardly dissolved in an aqueous alkaline solution to be used for e.g. development, separation and washing steps for the photoresist to be used at the time of patterning. Therefore, for the development, separation and washing steps, an aqueous alkaline solution can be used without using a flammable organic solvent, such being favorable in view of safety and environment.

In the case of carrying out patterning by removing part of the precursor film by a laser beam, the wavelength of the laser is, in a case where the substrate is glass, preferably a wavelength in near ultraviolet to visible region since the glass has low absorption characteristics and is less likely to be broken, and specifically it is from 350 to 600 nm, particularly preferably from 450 to 600 nm. The laser is preferably a YAG laser in view of processing accuracy, facility cost, etc. As the wavelength of the YAG laser, second harmonic (532 nm) or third harmonic (355 nm) may be exemplified in view of stability of an oscillator. By employing second harmonic or third harmonic, it is possible to make the laser spot diameter be a relatively large at a level of from 5 to 10 μm, and processing with a laser having such a spot diameter becomes possible, whereby the scanning rate can be increased, and efficient processing will be possible. The shape of the spot may be tetragonal (such as square) by employing e.g. a mask for shielding. It is preferred to employ a laser having such a spot shape, whereby a shape with corners can easily be formed.

After patterning, heat treatment is applied to the precursor film. The heat treatment temperature is preferably from 300 to 700° C. If it is less than 300° C., oxidation of the precursor film is less likely to proceed, such being unfavorable in view of transparency and electrical conductivity. Further, if it exceeds 700° C., oxygen in the crystal lattice in the tin oxide film tends to increase, and carrier electrons contributing to the electrical conductivity tend to decrease, whereby the electrical conductivity tends to be low. Further, deformation of the substrate tends to be significant, such being unfavorable in view of practical use. The heat treatment temperature is more preferably from 500 to 600° C. in view of electrical conductivity. The heat treatment time is preferably from 1 to 60 minutes. If it is less than 1 minute, oxidation of the precursor film is less likely to proceed, such being unfavorable in view of transparency and electrical conductivity of the tin oxide film to be formed. Further, the time exceeding 60 minutes is unfavorable in view of productivity. The heat treatment is carried out preferably in an oxidizing atmosphere or in the air in view of oxidation of the precursor film.

Further, in a case where a transparent electrode for a plasma display is to be formed, the heat treatment may be carried out simultaneously with heat treatment in a step of melting a frit paste (low-melting glass for sealing) for sealing. Therefore, the present invention is particularly suitable as a process for producing a transparent electrode for a plasma display, since no special apparatus has to be provided for the heat treatment.

Further, the tin oxide film may contain at least one additive metal selected from the group consisting of antimony, tantalum, tungsten and rhenium. The above additive metal will function as an additive (dopant) which imparts further electrical conductivity and heat resistivity to tin oxide. Further, the additive metal is preferably present in a state where it is solid-solubilized in tin oxide in the film. The amount of the additive metal is preferably from 0.1 to 30 atomic % to Sn, more preferably from 0.1 to 25 atomic % in view of improvement in electrical conductivity and heat resistivity. It is more preferably from 0.1 to 10 atomic % with a view to obtaining a transparent electrode having lower resistivity.

The formed tin oxide film is a film containing tin oxide as the main component, and it is preferred that the content of metal elements other than Sn and the above additive metal is at most 20 atomic % to Sn, with a view to not impairing excellent properties of tin oxide such as electrical conductivity and transparency. Further, the metal elements are basically preferably present in a state where they are oxidized in the film, with a view to not impairing excellent properties of tin oxide such as electrical conductivity and transparency. Further, a light element such as nitrogen or carbon may be contained within a range not to impair the characteristics of the present invention.

The thickness of the tin oxide film is preferably from 100 to 500 nm, particularly preferably from 100 to 300 nm as the geometrical film thickness in view of transparency and electrical conductivity. It is also possible to provide another layer as an undercoat layer of the tin oxide film to obtain a film comprising two or more layers. The change in film thickness is small and at most 37% between before and after the heat treatment and patterning.

The sheet resistivity of the transparent electrode of the present invention is preferably from 5 to 5,000 Ω/□, particularly preferably from 10 to 3,000 Ω/□, or from 10 to 400 Ω/□, with a view to sufficiently obtaining properties of the transparent electrode. Further, the visible light transmittance of the transparent electrode is preferably at least 75%, particularly preferably from 80 to 100%, with a view to sufficiently obtaining properties of the transparent electrode.

The substrate is preferably a glass substrate in view of transparency and heat resistivity of the substrate. The glass substrate may, for example, be soda lime glass, particularly high strain point glass for a plasma display or an inorganic EL. In the case of soda lime glass, one coated with silicon oxide is suitably used. The thickness of the glass substrate is preferably from 0.3 to 5 mm, particularly preferably from 2.0 to 3.0 mm in view of durability. The luminous transmittance of the substrate is preferably at least 80% in view of transparency.

Now, the present invention will be described in detail with reference to Examples and Comparative Examples. However, it should be understood that the present invention is by no means restricted to such specific Examples.

### EXAMPLE 1

A high strain point glass (PD200, manufactured by Asahi Glass Company, Limited) having a thickness of 2.8 mm was prepared as a substrate. The glass substrate was washed and set in a substrate holder. A SnO₂ oxide sintered target (manufactured by MITSUI MINING & SMELTING CO., LTD.) having 3 atomic % of Sb added to Sn was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As the sputtering gas, an argon gas was used. The substrate temperature was 80° C. The pressure was 1.2 Pa at the time of deposition. The obtained film was a film colored yellow, whereby presence of oxygen deficiencies in the film was estimated. The visible light transmittance of the glass substrate provided with the obtained film was 81%. The density of the formed film was 4.9 g/cm³.

Further, crystallinity of the film was measured by X-ray diffraction (RINT2100HK/PC manufactured by Rigaku Corporation) and as a result, no sharp peak was observed, and the film was found to be amorphous. The composition of the formed film was the same as that of the target. By heating the film colored yellow in the air at 600° C. for 30 minutes, the visible light transmittance Tᵥ of the glass substrate provided with the film was increased to 88%. The visible light transmittance of the film alone was calculated from the visible light transmittance of the glass substrate provided with the film. The visible light transmittance of the film increased by at least 3%, and the formed film was confirmed to be a colored tin oxide film.

Then, a mixed aqueous solution containing 1.8 mol/liter of FeCl₃ and 5 mol/liter HCl was prepared as an etching liquid. In order to pattern the SnO₂₋ₓ film formed on the glass substrate, a mask was formed by a resist resin on the colored tin oxide film by photolithography. The colored tin oxide film with the mask was immersed in the above etching liquid kept at 50° C. to carry out etching. The etching time was 5 minutes. A portion not covered with the mask of the colored tin oxide film was dissolved in the etching liquid, and a desired pattern could be formed. The etching rate was about 0.5 nm/sec. Then, washing with an alkaline solution was carried out to obtain a desired pattern.

Then, heat treatment was carried out in the air at 600° C. for 30 minutes to form a transparent electrode comprising tin oxide. No separation of the film nor cracks occurred. The transparent electrode had a visible light transmittance of 88% and a sheet resistivity of 500 Ω/□.

The visible light transmittance, the sheet resistivity and the density of the film were measured by the following methods.

(1) Visible light transmittance: Calculated from a transmission spectrum obtained by using a spectrophotometer (U-4100 manufactured by Shimadzu Corporation) in accordance with JIS-R3106 (1998).

(2) Sheet resistivity: Measured by a 4-pin probe method employing a surface resistivity measuring apparatus (LORESTA manufactured by Mitsubishi Petrochemical Co., Ltd.).

(3) Density of film: The amount of the Sn oxide film deposited on the film was measured by a fluorescent X-ray apparatus (RIX3000 manufactured by Rigaku Corporation). Assuming the compounds be SnO₂ and Sb₂O₃, the amount of SnO₂ and Sb₂O₃ deposited were calculated from the intensities of Sn—K_{α} and Sb—K_{α} rays in accordance with 15 fundamental parameter theoretical calculation, and the density was obtained from these values. Here, the density of a film formed on a silicon substrate can be calculated from the above method, but it was difficult to identify the composition of a film on a glass substrate, since signals from elements contained in the substrate which were the same as those in the composition of the film were calculated as a background. Therefore, the density of a film on a glass substrate was calculated assuming that it was formed on a silicon substrate.

### EXAMPLE 2

A high strain point glass (PD200, manufactured by Asahi Glass Company, Limited) having a thickness of 2.8 mm was prepared as a substrate. The glass substrate was washed and set in a substrate holder. A SnO₂ oxide sintered target having 10 atomic % of Sb added to Sn (a 6 inch circular SnO₂ target (manufactured by MITSUI MINING & SMELTING CO., LTD.) formed by mixing Sb₂O₃ and SnO₂ powders in a molar ratio of 10:90 and sintering the mixture) was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As the sputtering gas, an argon gas was used. Deposition was carried out at room temperature without heating the substrate, and the temperature was 70° C. The pressure was 3.3 Pa at the time of deposition. The visible light transmittance of the glass substrate provided with the obtained film was 86%. Further, the formed film had a density of 5.2 g/cm³.

Further, crystallinity of the film was measured by X-ray diffraction (RINT2100HK/PC manufactured by Rigaku Corporation) and as a result, no sharp peak was observed, and the film was found to be amorphous. The composition of the formed film was the same as that of the target. The formed film was heated in the air at 600° C. for 30 minutes, whereupon the visible light transmittance T, of the glass substrate provided with the film was 86% and remained substantially unchanged.

Patterning was carried out on the film with an etching liquid in the same manner as in Example 1, whereupon a portion not covered with a mask of the film was dissolved in the etching liquid, and the desired pattern could be formed. The etching rate was about 1.6 nm/sec. Then, washing with an alkaline solution was carried out to obtain a desired pattern.

Then, heat treatment was carried out in the air at 600° C. for 30 minutes to form a transparent electrode comprising tin oxide. No separation of the film nor cracks occurred. The transparent electrode had a visible light transmittance of 86% and a sheet resistivity of 300 Ω/□. The visible light transmittance, the sheet resistivity and the density of the film were measured in the same manner as in Example 1.

### EXAMPLE 3

A high strain point glass (PD200, manufactured by Asahi Glass Company, Limited) having a thickness of 2.8 mm was prepared as a substrate. The glass substrate was washed and set in a substrate holder. A SnO₂ oxide sintered target having 10 atomic % of Sb added to Sn (a 6 inch circular SnO₂ target (manufactured by MITSUI MINING & SMELTING CO., LTD.) formed by mixing Sb₂O₃ and SnO₂ powders in a molar ratio of 10:90 and sintering the mixture) was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As a sputtering gas, an argon gas was used. Deposition was carried out at room temperature without heating the substrate, and the temperature was 70° C. The electric power was 1,000 W. The gas pressure was changed within a range of from 1 to 4 Pa (gas pressures of 1.1 Pa, 1.6 Pa, 2.2 Pa, 2.7 Pa, 3.3 Pa and 4 Pa). A change of the deposition rate depending on the gas pressure is shown in FIG. 6. The deposition rate decreases together with the increase in the gas pressure, but the deposition rate is at least 4 nm/s for every film, and it is understood that films are prepared at a deposition rate sufficient for productivity.

Further, crystallinity of the film was measured by X-ray diffraction (RINT2100HK/PC manufactured by Rigaku Corporation) and as a result, no sharp peak was observed, and the film was found to be amorphous. The composition of the formed film was the same as that of the target. The visible light transmittance of the formed film increased by at least 3%, and the formed film was confirmed to be a colored tin oxide film.

Then, patterning was carried out on the film with an etching liquid in the same manner as in Example 1, whereupon it was confirmed that films prepared under gas pressures of at least 2.5 Pa were dissolved within 90 seconds. That is, an etching rate of at least about 1.6 nm/s was confirmed. This is an etching rate equal to that for a conventional ITO.

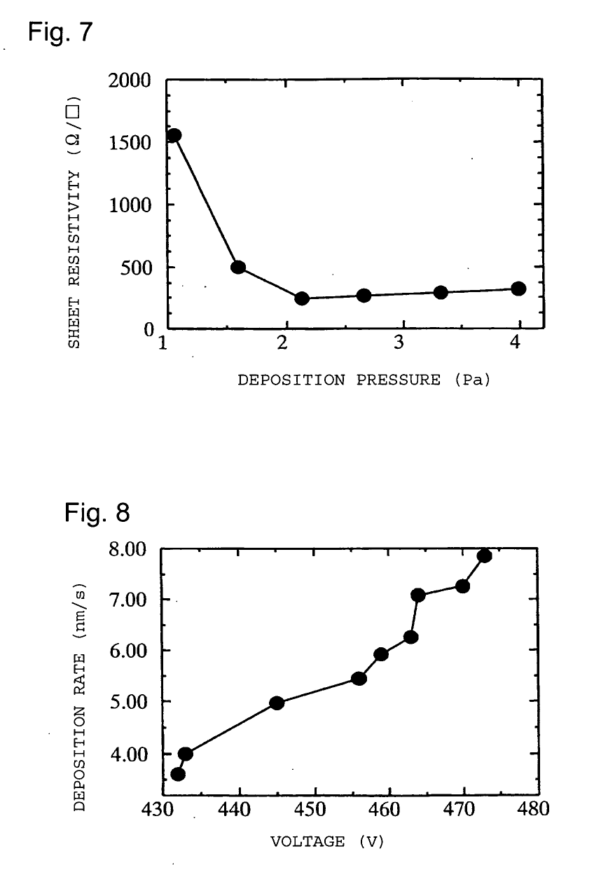

Then, heat treatment was carried out in the same manner as in Example 1. The visible light transmittance of each of the films obtained after the heat treatment was at least 85%. No separation of the film nor cracks occurred. The sheet resistivity of the tin oxide film depending on the gas pressure is shown in FIG. 7. With respect to films formed under gas pressures of at least 2 Pa, films having low resistivities of at most 300 Ω/□ were obtained. On the contrary, with respect to films formed under gas pressures less than 2 Pa, the resistivities were so high as at least 500 Ω/□. The visible light transmittance, the sheet resistivity and the density of the film were measured in the same manner as in Example 1.

### EXAMPLE 4

Films were prepared in the same manner as in Example 3 under the respective gas pressures except that a silicon substrate was used instead of the glass substrate and that the film thickness was 300 nm. As a result, it was confirmed that densities of films formed under gas pressures of at least 2 Pa were at most 6.5 g/cm³. On the contrary, densities of films formed under gas pressures less than 2 Pa were higher than 6.5 g/cm³.

### EXAMPLE 5

A high strain point glass (PD200 manufactured by Asahi Glass Company, Limited) having a thickness of 2.8 mm was prepared as a substrate. The glass substrate was washed and set in a substrate holder. A Sn metal target having 6 atomic % of Sb added to Sn (a 6 inch circular Sn metal target (manufactured by Asahi Glass Ceramics Co., Ltd.) formed by mixing Sb₂O₃ and Sn powders in a molar ratio of 5.9:94.1, followed by rubber pressing) was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As the sputtering gas, a gas mixture of an argon gas and an oxygen gas was used. The content of the oxygen gas in the sputtering gas was 20 vol %. Deposition was carried out at room temperature without heating the substrate, and the temperature was 70° C. The deposition rate was 6.3 nm/sec. The pressure was 3.3 Pa at the time of deposition. The electric power was 463 V. The obtained film was a film colored yellow, and presence of oxygen efficiencies in the film was estimated. The visible light transmittance of the glass substrate provided with the obtained film was 81%. When the film is represented as a SnO₂₋ₓ film, x is 0.5. The formed film had a density of 5.2 g/cm³.

Further, crystallinity of the film was measured by X-ray diffraction (RINT2100HK/PC manufactured by Rigaku Corporation) and as a result, no sharp peak was observed, and the film was found to be amorphous. The composition of the formed film was the same as that of the target. The film colored yellow was heated in the air at 600° C. for 30 minutes, whereupon the visible light transmittance Tᵥ of the glass substrate provided with the film increased to 88%. The visible light transmittance of the film alone was calculated from the visible light transmittance of the glass substrate provided with the film. The visible light transmittance of the film increased by at least 3%, and the formed film was confirmed to be a colored tin oxide film.

Then, patterning was carried out on the film with an etching liquid in the same manner as in Example 1 and as a result, a portion not covered with a mask of the film was dissolved in the etching liquid, and a desired pattern could be formed. The etching rate was about 1.6 nm/sec. Then, washing with an alkaline solution was carried out to obtain a desired pattern.

Then, heat treatment was carried out in the same manner as in Example 1 to form a transparent electrode comprising tin oxide. No peeling of the film nor cracks occurred. The transparent electrode had a visible light transmittance of 87% and a sheet resistivity of 190 Ω/□. The visible light transmittance, the sheet resistivity and the density of the film were measured in the same manner as in Example 1. When the film is represented as a SnO₂₋ₓ film, x is calculated employing a method of measuring the O/Sn ratio described hereinafter.

### EXAMPLE 6

A high strain point glass (PD200 manufactured by Asahi Glass Company, Limited) having a thickness of 2.8 mm was prepared as a substrate. The glass substrate was washed and set in a substrate holder. A Sn metal target having 6 atomic % of Sb added to Sn (a 6 inch circular Sn metal target (manufactured by Asahi Glass Ceramics Co., Ltd.) formed by mixing Sb₂O₃ and Sn powders in a molar ratio of 5.9:94.1, followed by rubber pressing) was attached to the cathode of a DC magnetron sputtering is apparatus. The deposition chamber of the sputtering apparatus was evacuated of air, and a film containing tin oxide as the main component having a thickness of about 150 nm was formed on the glass substrate by a DC magnetron sputtering method. As the sputtering gas, a gas mixture of an argon gas and an oxygen gas was used. The content of the oxygen gas in the sputtering gas was 20 vol %. Deposition was carried out at room temperature without heating the substrate, and the temperature was 70° C. The pressure at the time of deposition was 3.3 Pa. Deposition was carried out by changing the voltage within a range of from 432 V to 473 V (voltages of 432 V, 433 V, 445V, 456 V, 459 V, 463 V, 464 V, 471 V and 473 V). The obtained films with voltages of at least 435 V were films colored yellow, and presence of oxygen efficiencies in the films was estimated. The change of the deposition rate depending on the voltage is shown in FIG. 8. The deposition rate increases along with the increase in the voltage, but the voltage rate is at least 4 nm/s when the voltage is at least 435 V, and it is understood that films can be prepared at deposition rates sufficient for productivity.

Then, patterning was carried out on the films with an etching liquid in the same manner as in Example 1 and as a result, a portion not covered with a mask of the film was dissolved in the etching liquid, and a desired pattern could be formed. It was confirmed that the films formed at voltages of at least 459 V were dissolved within 90 seconds. That is, etching rates of at least about 1.6 nm/s was confirmed. This is an etching rate equal to that for a conventional ITO.

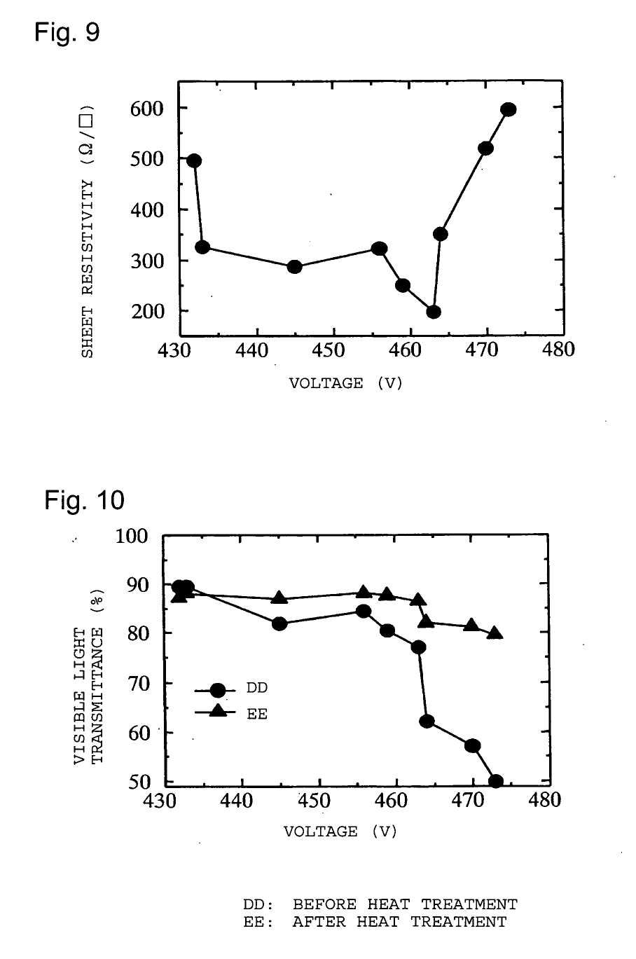

The change of the sheet resistivity of the formed films depending on the voltage is shown in FIG. 9. With respect to the films formed at voltages of from 455 to 465 V, films having low resistivities of at most 300 Ω/□ were obtained. The change of the visible light transmittance depending on the voltage before and after the heat treatment is shown in FIG. 10. The visible light transmittance increased by at least 3% by firing, and the films before the heat treatment are found to be light absorptive films. The films obtained after firing were transparent films having visible light transmittances of at least 85%. The visible light transmittance, the sheet resistivity and the density of the film were measured in the same manner as in Example 1.

### EXAMPLE 7

### Comparative Example

Deposition was carried out in the same manner as in Example 2 except that the gas pressure was changed from 3.3 Pa to 1 Pa and that the substrate temperature was changed from 80° C. to 400° C. The obtained film was a transparent film without coloring. Further, when the film is represented as a SnO₂₋ₓ film, x is 0.05. The density of the film was 7 g/cm³.

Crystallinity of the film was examined in the same manner as in Example 1, whereupon the film was found to be an amorphous film. The visible light transmittance of the substrate provided with the film after deposition was 88%, and the visible light transmittance remained substantially unchanged even after heating in the air at 600° C. for 30 minutes, whereupon it was found that the film was not a colored tin oxide film. Patterning could be carried out by immersing the film after deposition by sputtering in an etching liquid for 30 minutes in the same manner as in Example 1, but the pattern was dissolved in an alkaline solution at the time of washing, and no desired pattern could be obtained. The visible light transmittance, the sheet resistivity and the density of the film were measured in the same manner as in Example 1. When the film is represented as a SnO₂₋ₓ film, x is calculated employing a method of measuring the O/Sn ratio described hereinafter.

### EXAMPLE 8

A high strain point glass (PD200 manufactured by Asahi Glass Company, Limited, luminous transmittance: 90.2%) having a thickness of 2 mm was prepared as a substrate. The glass substrate was washed and set in a substrate holder of a DC magnetron sputtering apparatus. A flat Sn metal target (Sn: 99.99 mass %, manufactured by Kojundo Chemical Laboratory Co., Ltd.) in a size of 70 mm×200 mm×6 mm in thickness was attached to the cathode of the DC magnetron sputtering apparatus. The deposition chamber of the sputtering apparatus was evacuated of air, and a SnO₂₋ₓ film having a thickness of about 150 nm was formed on the glass substrate by a reactive sputtering method. As the sputtering gas, a gas mixture of an argon gas and an oxygen gas was used, and deposition was carried out at proportions of the oxygen gas in the sputtering gas as identified in Table 1 (samples 1 to 8). The substrate temperature was room temperature. The pressure was 0.3 Pa at the time of deposition.

The tin atom concentration and the oxygen atom concentration in the film sample 7 among the obtained films were measured employing ESCA by the following method to calculate the ratio (O/Sn ratio) of oxygen atoms to tin atoms. The O/Sn ratio was 0.45, whereby the value x of the SnO₂₋ₓ film was calculated to be 1.55. Further, the luminous transmittance of the substrate provided with the film sample 7 was 1.1%.

Then, a mixed aqueous solution containing 5 mass % of ferric chloride (FeCl₃) and 18 mass % of HCl was prepared as an etching liquid. In order to pattern the SnO₂₋ₓ film formed on the glass substrate, a mask was formed by a resist resin on the SnO₂₋ₓ film by photolithography. The SnO₂₋ₓ film with the mask was immersed in the etching liquid kept at 50° C. to carry out etching, and the etching rate was measured. The etching rate is shown in Table 1.

Then, heat treatment was carried out on the etched SnO₂₋ₓ film to form a transparent electrode. The thickness of the transparent electrode was 150 nm. The heat treatment was carried out by heating the film in the air for 1 hour and then heating the film at 600° C. for 60 minutes by an electric furnace (model FP410 manufactured by Yamato Scientific Co., Ltd.). No separation of the film nor cracks occurred. The luminous transmittance and the volume resistivity of the transparent electrode were measured by the following methods. The results are shown in Table 1.

The O/Sn ratio, the luminous transmittance, the volume resistivity and the film thickness were measured by the following methods.

(1) O/Sn ratio: Sputtering etching was carried out on a portion (10 mm in diameter) in the vicinity of the center of the formed film employing 800 eV Ar⁺ ion beam under such conditions that the SiO₂ film would be etched in an amount of 20 nm (conditions under which the etching was less likely to be influenced by the film surface), and the tin atom concentration and the oxygen atom concentration at the etched portion were measured employing an XPS measuring apparatus (JPS-9000 MC manufactured by JEOL Ltd.) As the X-ray source, Al—K_{α} (monochromatic) ray monochromatized by quartz crystal was employed, the beam diameter of the X-ray was 3×1 mm, and the output of the X-ray was 10 kV and 25 mA. Charge correction was carried out by a flat gun at ANODE-100 V, BIAS-10 V and FILAMENT 1.07 to 1.23 A. Photoelectron generated from the film by irradiation with X-ray was detected by a detector. The photoelectron detection angle was 80° and the incident energy path of the photoelectron in the energy analyzer was 20 eV.

Peaks of C₁₈, Sn_{3d5/2} and O_{1S} of the photoelectron observed were measured and the peak areas were determined to calculate the ratio (O/Sn) of oxygen atoms to tin atoms employing the following relative sensitivity coefficient.

Relative sensitivity coefficient

| | |
|---|---|
| C_{1S} | 4259 |
| Sn_{3d5/2} | 11914 |
| O_{1S} | 60033 |

(2) Luminous transmittance: Measured employing a luminous transmittance measuring apparatus (Model 305 manufactured by Asahi Spectra Co., Ltd.) in accordance with JIS-Z8722 (1982) with a reference 100% of a state without sample (the air), and the tristimulus value Y was taken as the luminous transmittance.

(3) Volume resistivity: The sheet resistivity was measured by a 4-pin probe method (LORESTA IP manufactured by Mitsubishi Chemical Corporation).

(4) Film thickness: Measured employing a stylus profiler (Dektak3030 manufactured by Sloan).

TABLE 1

| | Oxygen | | | |
|---|---|---|---|---|
| | concentration | | | |
| | at the time | | Luminous | Volume |
| | of deposition | Etching rate | transmittance | resistivity |
| Sample | (vol %) | (nm/sec) | (%) | (Ω · cm) |
| 1 | 0 | 4.26 | 11.2 | 2.96 |
| 2 | 30 | 4.53 | 50.5 | 1.17 |
| 3 | 35 | 3.35 | 66.8 | 0.66 |
| 4 | 40 | 0.43 | 69.3 | 0.75 |
| 5 | 44 | 0.26 | 52.4 | 0.88 |
| 6 | 47 | 0.45 | 50.0 | 0.26 |
| 7 | 50 | 0.03 | 70.3 | 0.15 |
| 8 | 53 | 0.00 | 74.8 | 0.12 |

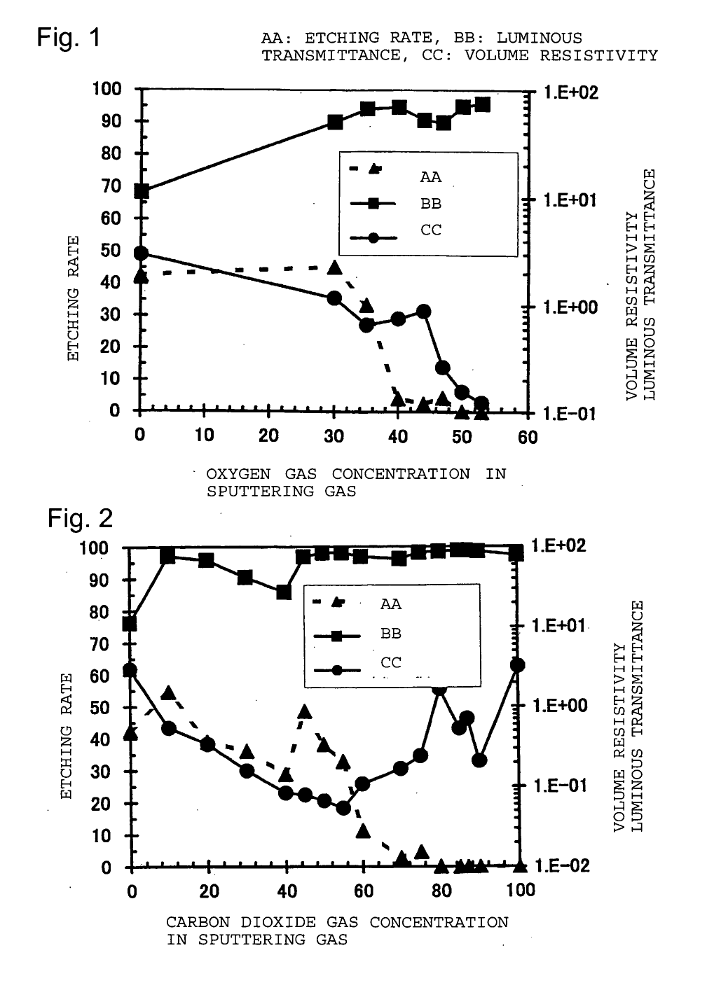

The data in Table 1 are shown in FIG. 1. Samples 2 to 7 correspond to Examples and samples 1 and 8 correspond to Comparative Examples.

### EXAMPLE 9

Deposition was carried out in the same manner as in Example 8 except that a gas mixture of an argon gas and a carbon dioxide gas was used instead of the gas mixture of an argon gas and an oxygen gas as the sputtering gas. Deposition was carried out at proportions of the carbon dioxide gas in the sputtering gas as identified in Table 2 (samples 9 to 24). The O/Sn ratio in the film sample 13 was measured in the same manner as in Example 8 and as a result, it was 0.33, whereby the value x in the SnO₂₋ₓ film was calculated to be 1.67.

The values x in the SnO₂₋ₓ films were calculated in the same manner and as a result, sample 14: 1.74, sample 15: 1.6, sample 17: 1.23, sample 20: 1.13, and sample 21: 1.0. Further, the luminous transmittance of the substrate provided with the film sample 15 was 0.04%.

The etching rates of the obtained films were measured in the same manner as in Example 8. The etching rates are shown in Table 2.

Then, heat treatment was carried out in the same manner as in Example 8 to form a transparent electrode. No peeling of the film nor cracks occurred. The luminous transmittance and the sheet resistivity of the transparent electrode were measured in the same manner as in Example 8. The results are shown in Table 2.

TABLE 2

| | Carbon | | | |
|---|---|---|---|---|
| | dioxide | | | |
| | concentration | | | |
| | at the time | | Luminous | Volume |
| | of deposition | Etching rate | transmittance | resistivity |
| Sample | (vol %) | (nm/sec) | (%) | (Ω · cm) |
| 9 | 0 | 4.26 | 11.2 | 2.96 |
| 10 | 10 | 5.47 | 76.4 | 0.54 |
| 11 | 20 | 3.90 | 68.3 | 0.34 |
| 12 | 30 | 3.63 | 41.8 | 0.16 |
| 13 | 40 | 2.90 | 27.3 | 0.08 |
| 14 | 45 | 4.87 | 74.9 | 0.08 |
| 15 | 50 | 3.83 | 84.3 | 0.07 |
| 16 | 55 | 3.30 | 84.3 | 0.05 |
| 17 | 60 | 1.14 | 75.3 | 0.11 |
| 18 | 70 | 0.30 | 70.4 | 0.17 |
| 19 | 75 | 0.47 | 84.5 | 0.24 |
| 20 | 80 | 0.01 | 87.2 | 1.67 |
| 21 | 85 | 0.00 | 89.4 | 0.53 |
| 22 | 87 | 0.00 | 89.3 | 0.70 |
| 23 | 90 | 0.00 | 87.0 | 0.21 |
| 24 | 100 | 0.00 | 78.0 | 3.20 |

The data in Table 2 are shown in FIG. 2. Samples 10 to 20 correspond to Examples, and samples 9 and 21 to 24 correspond to Comparative Examples.

### EXAMPLE 10

Deposition was carried out in the same manner as in Example 8 except that a gas mixture of an argon gas, an oxygen gas and a nitrogen gas was used instead of the gas mixture of an argon gas and an oxygen gas as the sputtering gas. Deposition was carried out at proportions of the oxygen gas and the nitrogen gas in the sputtering gas as identified in Table 3 (Samples 25 and 26). The formed films provided metallic colors in appearance, and they were thereby estimated to be SnO₂₋ₓ films.

The etching rates of the obtained films were measured in the same manner as in Example 8. The etching rates are shown in Table 3.

Then, heat treatment was carried out in the same manner as in Example 8 to form a transparent electrode. No separation of the film nor cracks occurred. The luminous transmittance and the sheet resistivity of the transparent electrode were measured in the same manner as in Example 8. The results are shown in Table 3. Samples 25 and 26 correspond to Examples.

TABLE 3

| | Oxygen | Nitrogen | | | |
|---|---|---|---|---|---|
| | concentration | concentration | | | |
| | at | at | | | |
| | the time | the time | | | |
| | of | of | | Luminous | |
| | deposition | deposition | Etching rate | transmittance | Volume resistivity |
| Sample | (vol %) | (vol %) | (nm/sec) | (%) | (Ω · cm) |
| 25 | 30 | 20 | 3.4 | 72.2 | 0.02 |
| 26 | 35 | 20 | 0.29 | 60.8 | 0.04 |

### EXAMPLE 11

Deposition was carried out in the same manner as in Example 8 except that a gas mixture of an argon gas, a carbon dioxide gas and a nitrogen gas was used instead of the as mixture of an argon gas and an oxygen gas as the sputtering gas. Deposition was carried out at proportions of the nitrogen gas in the sputtering gas as identified in Table 4 at a fixed proportion of the carbon dioxide gas in the sputtering gas of 30 vol % (samples 27 to 31). The formed films provided metallic colors in appearance, and they were thereby estimated to be SnO₂₋ₓ films.

The etching rates of the obtained films were measured in the same manner as in Example 8. The etching rates are shown in Table 4.

Then, heat treatment was carried out in the same manner as in Example 8 to form a transparent electrode. No separation of the film nor cracks occurred. The luminous transmittance and the sheet resistivity of the transparent electrode were measured in the same manner as in Example 8. The results are shown in Table 4.

TABLE 4

| | Nitrogen | | | |
|---|---|---|---|---|
| | concentration | | | |
| | at the time | | Luminous | Volume |
| | of deposition | Etching rate | transmittance | resistivity |
| Sample | (vol %) | (nm/sec) | (%) | (Ω · cm) |
| 27 | 0 | 3.63 | 68.3 | 0.16 |
| 28 | 20 | 3.34 | 53.2 | 0.70 |
| 29 | 30 | 0.94 | 44.0 | 0.17 |
| 30 | 40 | 0.31 | 41.6 | Measurement |
| | | | | impossible |
| 31 | 50 | 0.19 | 34.2 | Measurement |
| | | | | impossible |

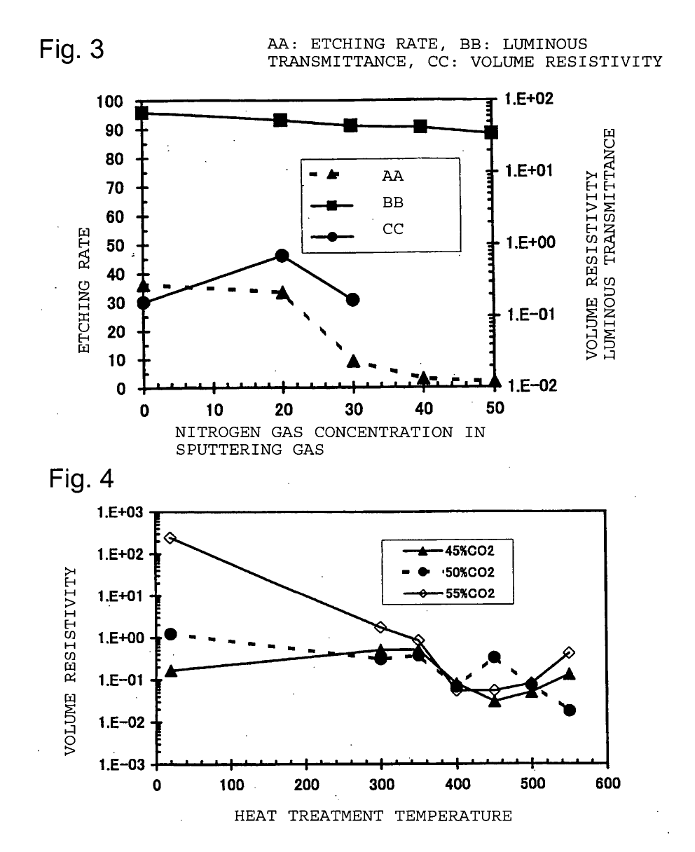

In Table 4, “measurement impossible” means that the resistivity was too high to be measured by a measuring apparatus. The data in Table 4 are shown in FIG. 3.

### EXAMPLE 12

Transparent electrodes were prepared in the same manner as in Example 9 except that the heat treatment temperature for samples 14, 15 and 16 was changed from 400° C. to the respective temperatures of 20° C., 300, 350, 450, 500 and 550° C. (samples 14-1 to 14-7, 15-1 to 15-7 and 16-1 to 16-7) (samples heated at 400° C. are shown again for reference). No separation of the film nor cracks occurred. The luminous transmittance and the sheet resistivity of the transparent electrode were measured in the same manner as in Example 8. The results are shown in Table 5.

TABLE 5

| | Carbon | | | |
|---|---|---|---|---|
| | dioxide | | | |
| | concentration | Heat | | |
| | at the time | treatment | Luminous | Volume |
| | of deposition | temperature | transmittance | resistivity |
| Sample | (vol %) | (° C.) | (%) | (Ω · cm) |
| 14-1 | 45 | 20 | 0.0 | 0.17 |
| 14-2 | 45 | 300 | 64.4 | 0.50 |
| 14-3 | 45 | 350 | 69.2 | 0.51 |
| 14-4 | 45 | 400 | 74.9 | 0.08 |
| 14-5 | 45 | 450 | 80.7 | 0.03 |
| 14-6 | 45 | 500 | 87.4 | 0.05 |
| 14-7 | 45 | 550 | 81.9 | 0.13 |
| 15-1 | 50 | 20 | 0.0 | 1.23 |
| 15-2 | 50 | 300 | 78.1 | 0.30 |
| 15-3 | 50 | 350 | 82.0 | 0.37 |
| 15-4 | 50 | 400 | 84.3 | 0.07 |
| 15-5 | 50 | 450 | 86.6 | 0.32 |
| 15-6 | 50 | 500 | 87.4 | 0.07 |
| 15-7 | 50 | 550 | 81.9 | 0.02 |
| 16-1 | 55 | 20 | 7.1 | 243.0 |
| 16-2 | 55 | 300 | 80.6 | 1.71 |
| 16-3 | 55 | 350 | 84.3 | 0.84 |
| 16-4 | 55 | 400 | 74.2 | 0.05 |
| 16-5 | 55 | 450 | 78.0 | 0.05 |
| 16-6 | 55 | 500 | 75.8 | 0.08 |
| 16-7 | 55 | 550 | 83.5 | 0.41 |

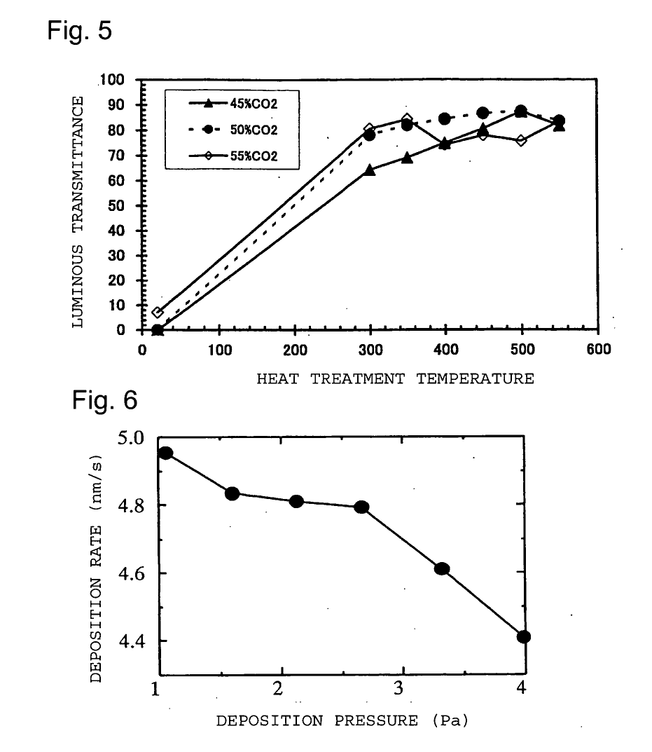

The data in Table 5 are shown in FIGS. 4 and 5. Samples 14-1, 15-1 and 16-1 correspond to Comparative Examples, and the other samples correspond to Examples.

### EXAMPLE 13

Deposition was carried out in the same manner as in Example 8 except that a Sn metal-dispersed target (manufactured by Asahi Glass Ceramics Co., Ltd.) having 1 atomic % tungsten metal fine particles dispersed in Sn was used instead of the Sn metal target as the target, and that the deposition gas pressure was 0.3 Pa, 0.8 Pa or 1.3 Pa (samples 32, 33 and 34).

The etching rates of the obtained films were measured in the same manner as in Example 8. The etching rates are shown in Table 6.

Then, heat treatment was carried out in the same manner as in Example 8 to form a transparent electrode. No peeling of the film nor cracks occurred. The luminous transmittance and the sheet resistivity of the transparent electrode were measured in the same manner as in Example 8. The results are shown in Table 7.

### EXAMPLE 14

Deposition was carried out in the same manner as in Example 9 except that a Sn metal-dispersed target (manufactured by Asahi Glass Ceramics Co., Ltd.) having 0.75 atomic % of tantalum metal fine particles dispersed in Sn was used instead of the Sn metal target as the target (sample 35).

The etching rate of the obtained film was measured in the same manner as in Example 8. The etching rate is shown in Table 6.

Then, heat treatment was carried out in the same manner as in Example 8 to form a transparent electrode. No separation of the film nor cracks occurred. The luminous transmittance and the sheet resistivity of the transparent electrode were measured in the same manner as in Example 8. The results are shown in Table 7.

TABLE 6

| | | Carbon | | | |
|---|---|---|---|---|---|
| | | dioxide | | | |
| | | concentration | | | |
| | | at | | | |
| | Deposition | the time | Etching | | |
| | gas | of | rate | Luminous | Volume |
| | pressure | deposition | (nm/ | transmittance | resistivity |
| Sample | (Pa) | (vol %) | sec) | (%) | (Ω · cm) |
| 32 | 0.3 | 25 | 16.1 | 1.0 | 0.03 |
| 33 | 0.8 | 20 | 16.7 | 1.1 | 0.05 |
| 34 | 1.3 | 15 | 17.3 | 1.7 | 0.003 |
| 35 | 0.3 | 30 | 14.3 | 0.1 | 0.08 |

TABLE 7

| | Heat | | |
|---|---|---|---|
| | treatment | Luminous | Volume |
| | temperature | transmittance | resistivity |
| Sample | (° C.) | (%) | (Ω · cm) |
| 32 | 580 | 82.1 | 0.006 |
| 33 | 580 | 80.7 | 0.005 |
| 34 | 580 | 77.2 | 0.007 |
| 35 | 580 | 77.9 | 0.014 |

### EXAMPLE 15

### Laser Patterning

A high strain point glass (PD200, manufactured by Asahi Glass Company, Limited, visible light transmittance of substrate: 91%) having a thickness of 2.8 mm was prepared as a glass substrate. The glass substrate was washed and set in a substrate holder. A SnO₂ oxide sintered target (manufactured by MITSUI MINING & SMELTING CO., LTD.) having 3 atomic % of Sb added to Sn was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As the sputtering gas, an argon gas was used. The substrate temperature was 80° C. The pressure was 0.4 Pa at the time of deposition.

The obtained film was a film colored yellow, whereby presence of oxygen deficiencies in the film was estimated. The visible light transmittance of the glass substrate provided with the obtained film was 81%. Further, the crystallinity of the film was measured by X-ray diffraction (RINT2100HK/PC manufactured by Rigaku Corporation) and as a result, no sharp peak was observed, whereby the film was found to be amorphous. The composition of the formed film was the same as that of the target. The film colored yellow was heated in the air at 600° C. for 30 minutes, whereby the visible light transmittance Tᵥ of the glass substrate provided with a film increased to 88%. The visible light transmittance of the film increased by at least 3%, whereby the formed film was confirmed to be a colored tin oxide film. The absorptivity of the formed film alone at the laser wavelength (532 nm) was 8%.

Then, the glass substrate provided with the film was put on a processing table of a laser processing machine (laser scriber manufactured by NEC Corporation) so that the film faced the laser irradiation side. The film was removed under conditions such that laser wavelength: 532 nm (second harmonic), output: single 50 W, one side of square spot: 50 μm and scan rate: 180 mm/s to form a desired pattern.

Then, heat treatment was carried out in the air at 600° C. for 30 minutes to form a transparent electrode having a desired pattern. No separation of the film nor cracks occurred. The transparent electrode had a visible light transmittance of 88% and a sheet resistivity of 500 Ω/□. The film thickness was 150 nm. The visible light transmittance remained unchanged even after the formed film was heated in the air at 600° C. for 30 minutes, whereby the film was confirmed to be a tin oxide film.

The visible light transmittance, the absorptivity and the sheet resistivity were measured by the following methods.

(1) Visible light transmittance: The visible light transmittance of the glass substrate provided with the film was calculated from the transmission spectrum of the glass substrate provided with the film, employing a spectrophotometer (U-4100 manufactured by Shimadzu Corporation) in accordance with JIS R3106 (1998).

(2) Absorptivity: The transmittance (including the glass substrate) of the substrate provided with the film and the reflectivity (the rear side of the glass substrate was coated with a light absorber so that the reflectivity could be measured under conditions where there was no reflection on the rear side) were measured employing a spectrophotometer used in (1), and the absorptivity was determined by calculation from the formula: absorptivity (%)=100-(transmittance (%)+reflectivity (%))

(3) Sheet resistivity: Measured employing a surface resistivity measuring apparatus (LORESTA manufactured by Mitsubishi Petrochemical Co., Ltd.).

### EXAMPLE 16

A high strain point glass (PD200, manufactured by Asahi Glass Company, Limited, visible light transmittance of substrate: 91%) having a thickness of 2.8 mm was prepared as a glass substrate. The glass substrate was washed and set in a substrate holder. A Sn alloy target (manufactured by Asahi Glass Company, Limited) having 3 atomic % of Sb added to Sn was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As the sputtering gas, a gas mixture of an argon gas and an oxygen gas was used, and the amount of the oxygen gas was 20 vol % to the entire sputtering gas. The substrate temperature was 80° C. The pressure was 0.4 Pa at the time of deposition.

The obtained film was a film colored amber, whereby presence of oxygen deficiencies in the film was estimated. The visible light transmittance of the glass substrate provided with the obtained film was 53%. Further, the crystallinity of the film was measured by X-ray diffraction (RINT2100HK/PC manufactured by Rigaku Corporation) and as a result, no sharp peak was observed, whereby the film was found to be amorphous. The film colored yellow was heated in the air at 600° C. for 30 minutes, whereby the visible light transmittance Tᵥ of the glass substrate provided with the film increased to 88%. The visible light transmittance of the film increased by at least 3%, whereby the formed film was confirmed to be a colored tin oxide film. The absorptivity of the formed film alone at the laser wavelength (532 nm) was 18%.

Then, the glass substrate provided with the film was put on a processing table of a laser processing machine (laser scriber manufactured by NEC Corporation) so that the film faced the laser irradiation side. The film was removed under conditions such that laser wavelength: 532 nm (second harmonic), output: single 50 W, one side of square spot: 50 μm and scan rate: 180 mm/s to form a desired pattern.

Then, heat treatment was carried out in the air at 600° C. for 30 minutes to form a transparent electrode having a desired pattern. No separation of the film nor cracks occurred. The transparent electrode had a visible light transmittance of 88% and a sheet resistivity of 500 Ω/□. The film thickness was 150 nm. The visible light transmittance remained unchanged even after the formed film was heated in the air at 600° C. for 30 minutes, whereby the film was confirmed to be a tin oxide film.

The visible light transmittance, the absorptivity and the sheet resistivity were measured in the same manner as in Example 15.

### EXAMPLE 17

### Comparative Example

A high strain point glass (PD200, manufactured by Asahi Glass Company, Limited, visible light transmittance of substrate: 91%) having a thickness of 2.8 mm was prepared as a glass substrate. The glass substrate was washed and set in a substrate holder. A Sn alloy target (manufactured by Asahi Glass Company, Limited) having 3 atomic % of Sb added to Sn was attached to the cathode of a DC magnetron sputtering apparatus. The deposition chamber of the sputtering apparatus was evacuated of air, and a film containing tin oxide as the main component having a thickness of about 150 nm was formed on the glass substrate by a DC magnetron sputtering method. As the sputtering gas, a gas mixture of an argon gas and an oxygen gas was used, and the amount of the oxygen gas was 90 vol % to the entire sputtering gas. The substrate temperature was 80° C. The pressure was 0.4 Pa at the time of deposition.

The obtained film was a colorless transparent film, whereby absence of oxygen deficiencies in the film was estimated. The visible light transmittance of the glass substrate provided with the obtained film was 88%. Further, crystallinity of the film was measured by X-ray diffraction method (RINT2100HK/PC manufactured by Rigaku Corporation) and as a result, peaks by which the film could be identified as SnO₂ were observed, and the film was found to be crystalline. Even after the glass substrate provided with the film was heated in the air at 600° C. for 30 minutes, the visible light transmittance Tᵥ of the glass substrate provided with the film was 88% and remained unchanged. Further, the absorptivity of the formed film alone at the laser wavelength (532 nm) was 4%.

Then, the glass substrate provided with the film was put on a processing table of a laser processing machine (laser scriber manufactured by NEC Corporation) so that the film faced the laser irradiation side. The film could not be removed under conditions such that laser wavelength: 532 nm (second harmonic), output: single 50 W, one side of square spot: 50 μm and scan rate: 180 mm/s, and no desired pattern could be formed.

Industrial Applicability

According to the process for producing a transparent electrode of the present invention, a patterned tin oxide film can readily be formed, and the formed tin oxide film has low resistivity and is excellent in transparency. Therefore, the process of the present invention is useful as a process for producing an electrode particularly for a flat panel display.

The entire disclosures of Japanese Patent Application No. 2004-032039 (filed on Feb. 9, 2004), Japanese Patent Application No. 2004-048426 (filed on Feb. 24, 2004) and Japanese Patent Application No. 2004-099057 (filed on Mar. 30, 2004) including specifications, claims, drawings and summaries are incorporated herein by reference in their entireties.

What is claimed is:

1. A process for producing a transparent electrode having a patterned tin oxide film formed on a substrate, which comprises a step of forming a tin oxide film having light absorption characteristics on a substrate, a patterning step of removing part of the tin oxide film having light absorption characteristics, and a step of subjecting the patterned tin oxide film having light absorption characteristics to heat treatment to obtain a tin oxide film.

2. The process for producing a transparent electrode according to claim 1, wherein the step of forming a tin oxide film having light absorption characteristics is carried out by a sputtering method, and the temperature of the substrate at the time of deposition is at most 150° C.

3. The process for producing a transparent electrode according to claim 2, wherein in the sputtering method, the deposition is carried out by using an oxide target, and the amount of an oxidizing gas in a sputtering gas is at most 10 vol % of the entire sputtering gas.

4. The process for producing a transparent electrode according to claim 2, wherein in the sputtering method, the deposition is carried out by using a metal target.

5. The process for producing a transparent electrode according to claim 1, wherein the tin oxide film is a crystalline film.

6. The process for producing a transparent electrode according to claim 1, wherein the temperature at the time of the heat treatment is from 300 to 700° C.

7. The process for producing a transparent electrode according to claim 1, wherein the tin oxide film contains at least one additive metal selected from the group consisting of titanium, niobium, zirconium, antimony, tantalum, tungsten and rhenium.

8. The process for producing a transparent electrode according to claim 7, wherein the amount of the additive metal is from 0.1 to 30 atomic % to Sn.

9. The process for producing a transparent electrode according to claim 1, wherein the patterning is carried out by dissolving part of the film by an etching liquid.

10. The process for producing a transparent electrode according to claim 1, wherein the patterning is carried out by removing part of the film by a laser beam, and the wavelength of the laser beam is from 350 to 600 nm.

11. The process for producing a transparent electrode according to claim 1, wherein the patterning is carried out by removing part of the film by a laser beam, the wavelength of the laser beam is from 350 to 600 nm, and the absorptivity of the film at the wavelength of the laser beam is at least 5%.

12. The process for producing a transparent electrode according to claim 1, wherein the transparent electrode has a sheet resistivity of from 5 to 5,000 Ω/□.

13. A transparent electrode film formed by the production process as defined in claim 1.

14. A process for producing a transparent electrode having a patterned tin oxide film formed on a substrate, which comprises a step of forming a SnO₂₋ₓ (0.3≦x≦1.95) film on a substrate, a patterning step of removing part of the SnO₂₋ₓ film, and a step of subjecting the patterned SnO₂₋ₓ film to heat treatment to obtain a tin oxide film.

15. The process for producing a transparent electrode according to claim 14, wherein the step of forming a SO₂₋ₓ film is carried out by a sputtering method, and the temperature of the substrate at the time of deposition is at most 150° C.

16. The process for producing a transparent electrode according to claim 15, wherein in the sputtering method, the deposition is carried out by using an oxide target, and the amount of an oxidizing gas in a sputtering gas is at most 10 vol % of the entire sputtering gas.

17. The process for producing a transparent electrode according to claim 15, wherein in the sputtering method, the deposition is carried out by using a metal target.

18. The process for producing a transparent electrode according to claim 14, wherein the tin oxide film is a crystalline film.

19. The process for producing a transparent electrode according to claim 14, wherein the temperature at the time of the heat treatment is from 300 to 700° C.

20. The process for producing a transparent electrode according to claim 14, wherein the tin oxide film contains at least one additive metal selected from the group consisting of titanium, niobium, zirconium, antimony, tantalum, tungsten and rhenium.

21. The process for producing a transparent electrode according to claim 20, wherein the amount of the additive metal is from 0.1 to 30 atomic % to Sn.

22. The process for producing a transparent electrode according to claim 14, wherein the patterning is carried out by dissolving part of the film by an etching liquid.

23. The process for producing a transparent electrode according to claim 14, wherein the patterning is carried out by removing part of the film by a laser beam, and the wavelength of the laser beam is from 350 to 600 nm.

24. The process for producing a transparent electrode according to claim 14, wherein the patterning is carried out by removing part of the film by a laser beam, the wavelength of the laser beam is from 350 to 600 nm, and the absorptivity of the film at the wavelength of the laser beam is at least 5%.

25. The process for producing a transparent electrode according to claim 14, wherein the transparent electrode has a sheet resistivity of from 5 to 5,000 Ω/□.

26. A transparent electrode film formed by the production process as defined in claim 14.

27. A process for producing a transparent electrode having a patterned tin oxide film formed on a substrate, which comprises a step of forming a tin oxide film having a density of at most 6.5 g/cm³ on a substrate, a patterning step of removing part of the tin oxide film having a density of at most 6.5 g/cm³, and a step of subjecting the patterned tin oxide film having a density of at most 6.5 g/cm³ to heat treatment to obtain a tin oxide film.

28. The process for producing a transparent electrode according to claim 27, wherein the step of forming a tin oxide film having a density of at most 6.5 g/cm³ is carried out by a sputtering method, and the temperature of the substrate at the time of deposition is at most 150° C.

29. The process for producing a transparent electrode according to claim 28, wherein in the sputtering method, the deposition is carried out by using an oxide, and the amount of an oxidizing gas in a sputtering gas is at most 10 vol % of the entire sputtering gas.

30. The process for producing a transparent electrode according to claim 28, wherein in the sputtering method, the deposition is carried out by using a metal target.

31. The process for producing a transparent electrode according to claim 27, wherein the tin oxide film is a crystalline film.

32. The process for producing a transparent electrode according to claim 27, wherein the temperature at the time of the heat treatment is from 300 to 700° C.

33. The process for producing a transparent electrode according to claim 27, wherein the tin oxide film contains at least one additive metal selected from the group consisting of titanium, niobium, zirconium, antimony, tantalum, tungsten and rhenium.

34. The process for producing a transparent electrode according to claim 33, wherein the amount of the additive metal is from 0.1 to 30 atomic % to Sn.

35. The process for producing a transparent electrode according to claim 27, wherein the patterning is carried out by dissolving part of the film by an etching liquid.

36. The process for producing a transparent electrode according to claim 27, wherein the patterning is carried out by removing part of the film by a laser beam, and the wavelength of the laser beam is from 350 to 600 nm.

37. The process for producing a transparent electrode according to claim 27, wherein the patterning is carried out by removing part of the film by a laser beam, the wavelength of the laser beam is from 350 to 600 nm, and the absorptivity of the film at the wavelength of the laser beam is at least 5%.

38. The process for producing a transparent electrode according to claim 27, wherein the transparent electrode has a sheet resistivity of from 5 to 5,000 Ω/□.

39. A transparent electrode film formed by the production process as defined in claim 27.

40. A film capable of being patterned and forming a patterned tin oxide film on a substrate, which is a tin oxide film having light absorbing characteristics.

41. A film capable of being patterned and forming a patterned tin oxide film on a substrate, which is a SnO₂₋ₓ (0.3≦x≦1.95) film.

42. A film capable of being patterned and forming a patterned tin oxide film on a substrate, which is a tin oxide film having a density of at most 6.5 g/cm³.
